(19) United States
(12) Patent Application Publication
(10) Pub. No.: US 2014/0345523 A1
(43) Pub. Date: Nov. 27, 2014

(54) SUBSTRATE EJECTION DETECTION DEVICE, METHOD OF DETECTING SUBSTRATE EJECTION AND SUBSTRATE PROCESSING APPARATUS

(71) Applicant: Tokyo Electron Limited, Tokyo (JP)

(72) Inventors: Hitoshi KIKUCHI, Iwate (JP); Takeshi Kobayashi, Iwate (JP); Mitsuhiro Yoshida, Iwate (JP); Yuta Haga, Iwate (JP); Yuji Takabatake, Iwate (JP); Naohide Ito, Iwate (JP); Katsuaki Sugawara, Iwate (JP); Masaaki Chiba, Iwate (JP); Hiroyuki Sato, Iwate (JP)

(73) Assignee: Tokyo Electron Limited, Tokyo (JP)

(21) Appl. No.: 14/284,536

(22) Filed: May 22, 2014

(30) Foreign Application Priority Data
May 27, 2013 (JP) 2013-110870
Mar. 4, 2014 (JP) 2014-041758

(51) Int. Cl. C23C 16/52; G01B 11/14; G01B 21/16

(52) U.S. Cl. CPC C23C 16/52; G01B 21/16; G01B 11/14
USPC 118/712; 374/10; 356/614

(57) ABSTRACT

A substrate ejection detection device is used for substrate processing apparatus configured to process a substrate by continuously rotating a turntable holding the substrate on a concave portion formed in a surface thereof to receive the substrate thereon. In the substrate processing device, the turntable is substantially horizontally provided in a chamber. The substrate ejection detection device includes a substrate ejection determination unit configured to determine whether the substrate is out of the concave portion by determining whether the substrate exists on the concave portion while rotating the turntable.

### CROSS-REFERENCE TO RELATED APPLICATIONS

This patent application is based upon and claims the benefit of priority of Japanese Patent Application No. 2013-110870, filed on May 27, 2013, and Japanese Patent Application No. 2014-41758, filed on Mar. 4, 2014, the entire contents of which are incorporated herein by reference.

### BACKGROUND OF THE INVENTION

1. Field of the Invention

The present invention relates to a substrate ejection detection device, a method of detecting a substrate ejection and a substrate processing apparatus.

2. Description of the Related Art

Conventionally, as disclosed in Japanese Laid-Open Patent Application Publication No. H09-115994, an ion implantation apparatus is known that allows wafers to be disposed on a platen, performs ion implantation while clamping the wafer by using a clamp ring capable of pressing a periphery of the wafer, and includes a displacement detection unit that detects a displacement of the clamp in order to recognize abnormality such as wafers piled up on the same location of the platen.

Moreover, Japanese Laid-Open Patent Application Publication No. 2011-111651 discloses a chemical vapor deposition apparatus that allows an object to be processed to be placed on a turntable and processes the wafer thereon. In the chemical vapor deposition apparatus, the turntable and a support to support the turntable are made of materials different from each other, and when positional discrepancy has occurred with the result that a position of the turntable relative to the support is changed in a high temperature atmosphere due to a difference in coefficient of thermal expansion, the discrepancy is detected as a position gap, and then an alarm is issued, or the apparatus is stopped, when the position gap is equal to or more than a predetermined range.

In the meantime, a film deposition apparatus is known that deposits a film by an ALD (Atomic Layer Deposition) method or a MLD method (Molecular Layer Deposition). For example, the film deposition apparatus includes a chamber, and a turntable provided in the chamber and including a recess having a circular depressed shape and formed in a surface thereof. The film deposition apparatus deposits a film by rotating the turntable receiving a wafer on the recess and by supplying source gases in a plurality of process areas provided divided in a circumferential direction when the wafer passes the process areas in series.

In such a film deposition apparatus utilizing the ALD method or the MLD method (which is hereinafter called “an ALD film deposition apparatus”), a fixing unit to clamp the wafer into the recess by using a claw and the like cannot be used in terms of uniformity of the film deposition because the claw covers a part of a surface of the wafer. Furthermore, even though the temperature is not as high as the above-mentioned chemical vapor deposition apparatus, because the inside of the chamber is heated to a high temperature, when the wafer is transferred into the chamber, a phenomenon that the wafer warps on the recess is caused in many cases because the atmosphere surrounding the wafer rapidly changes from room temperature to the high temperature. In addition, in the ALD film deposition apparatus, because rotating the turntable is necessary to deposit a film, the turntable starts to rotate after the wafer is transferred into the chamber and the warpage of the wafer subsides. However, if the rotation is mistakenly started before the warpage has not subsided yet, the wafer is released from the recess. Moreover, some abnormality other than the warpage of the wafer can cause the wafer to be ejected from the rotating turntable. In such a case, if the ejection of the wafer cannot be promptly detected, the turntable continues to rotate with the wafer ejected, which is liable to cause various components and other unejected wafers in the chamber to be damaged.

On the other hand, since the invention disclosed in Japanese Laid-Open Patent Application Publication No. H09-115994 relates to the substrate processing apparatus including the clamp mechanism, the disclosed invention cannot be applied to the ALD film deposition apparatus. Furthermore, since the invention disclosed in Japanese Laid-Open Patent Application Publication No. 2011-111651 is to detect the position gap of the turntable relative to the support, the above-mentioned matter about the ejection of wafer cannot be resolved by the disclosed invention.

### SUMMARY OF THE INVENTION

Embodiments of the present invention provide a substrate ejection detection device, a method of detecting ejection of a substrate and a substrate processing apparatus solving one or more of the problems discussed above.

More specifically, the embodiments of the present invention may provide a substrate ejection detection device, a method of detecting ejection of a substrate and a substrate processing apparatus that can monitor and detect ejection of a substrate from a turntable while processing the substrate when using a substrate processing apparatus that processes the substrate by rotating the turntable.

According to one embodiment of the present invention, there is provided a substrate ejection detection device used for substrate processing apparatus configured to process a substrate by continuously rotating a turntable holding the substrate on a concave portion formed in a surface thereof to receive the substrate thereon. In the substrate processing device, the turntable is substantially horizontally provided in a chamber. The substrate ejection detection device includes a substrate ejection determination unit configured to determine whether the substrate is out of the concave portion by determining whether the substrate exists on the concave portion while rotating the turntable.

According to another embodiment of the present invention, there is provided a substrate processing apparatus including a chamber, a turntable substantially horizontally provided in the chamber and including a concave portion formed in a surface thereof to receive the substrate thereon, and a substrate ejection determination unit configured to determine whether the substrate is out of the concave portion by determining whether the substrate exists on the concave portion while rotating the turntable.

According to another embodiment of the present invention, there is provided a method of detecting substrate ejection used for substrate processing apparatus configured to process a substrate by continuously rotating a turntable holding the substrate on a concave portion formed in a surface thereof to receive the substrate thereon. In the method, whether the substrate is out of the concave portion is determined by determining whether the substrate exists or not on the concave portion while rotating the turntable.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a configuration diagram illustrating an example of a substrate ejection detection device and a substrate processing apparatus using the same according to an embodiment of the present invention;

FIG. 2 is a perspective view of a substrate processing apparatus according to an embodiment of the present invention;

FIG. 3 is a top view illustrating an inner structure of a substrate processing apparatus according to an embodiment of the present invention;

FIG. 4 is a cross-sectional view of a substrate processing apparatus along a concentric circle of a turntable according to an embodiment of the present invention;

FIG. 5 is a cross-sectional view illustrating an area provided with a ceiling surface of a substrate processing apparatus according to an embodiment of the present invention;

FIGS. 6A through 6D are explanation drawings of ejection of a wafer detected by a substrate ejection detection device according to an embodiment of the present invention;

FIG. 7 is a drawing illustrating a configuration of a substrate ejection detection device according to a first embodiment of the present invention;

FIGS. 8A and 8B are explanation drawings of radiation temperature detection and ejection determination by the substrate ejection detection device according to the first embodiment of the present invention;

FIGS. 9A and 9B are drawings illustrating an example of a substrate ejection detection device according to a second embodiment of the present invention;

FIG. 10 is a drawing illustrating an example of a substrate ejection determination performed at a determination part of the substrate ejection detection device according to a second embodiment of the present invention;

FIGS. 11A and 11B are drawings illustrating an example of a substrate ejection detection device according to a third embodiment of the present invention;

FIGS. 12A and 12B are drawings illustrating an example of a substrate ejection detection device according to a fourth embodiment of the present invention; and

FIGS. 13A and 13B are drawings illustrating an example of a substrate ejection detection device according to a fifth embodiment of the present invention.

### DETAILED DESCRIPTION OF THE PREFERRED EMBODIMENTS

A description is given below of embodiments of the present invention, with reference to accompanying drawings.

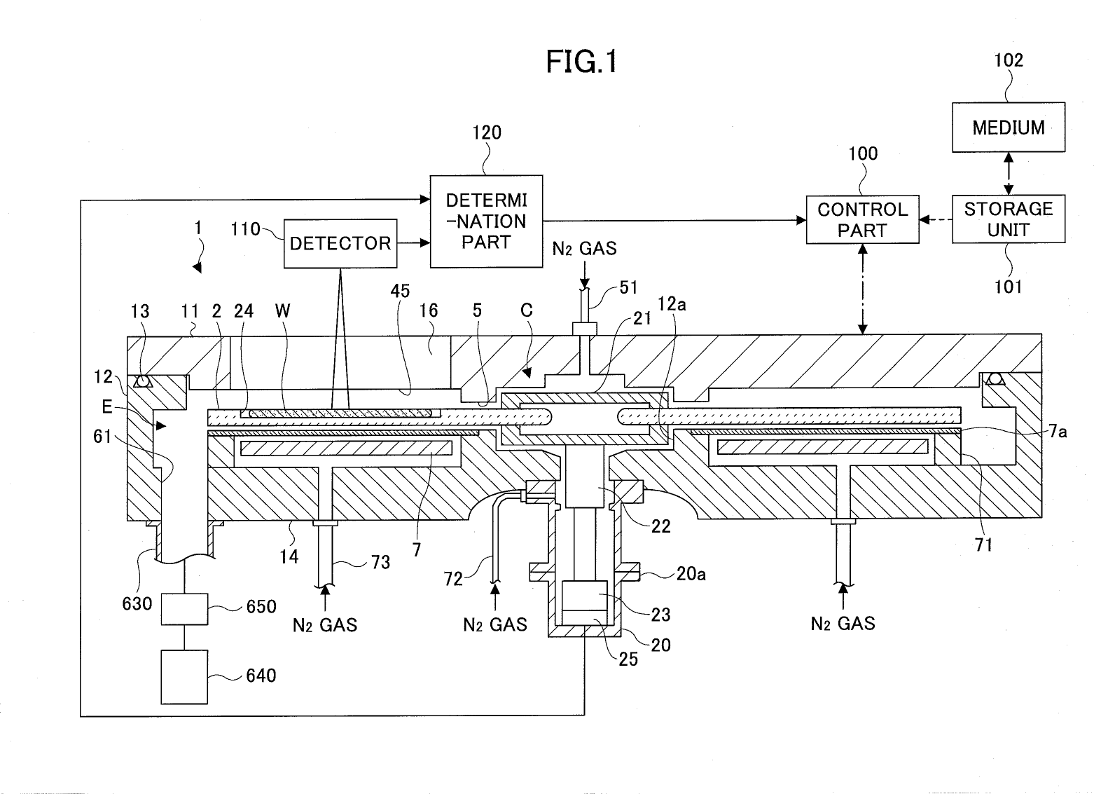

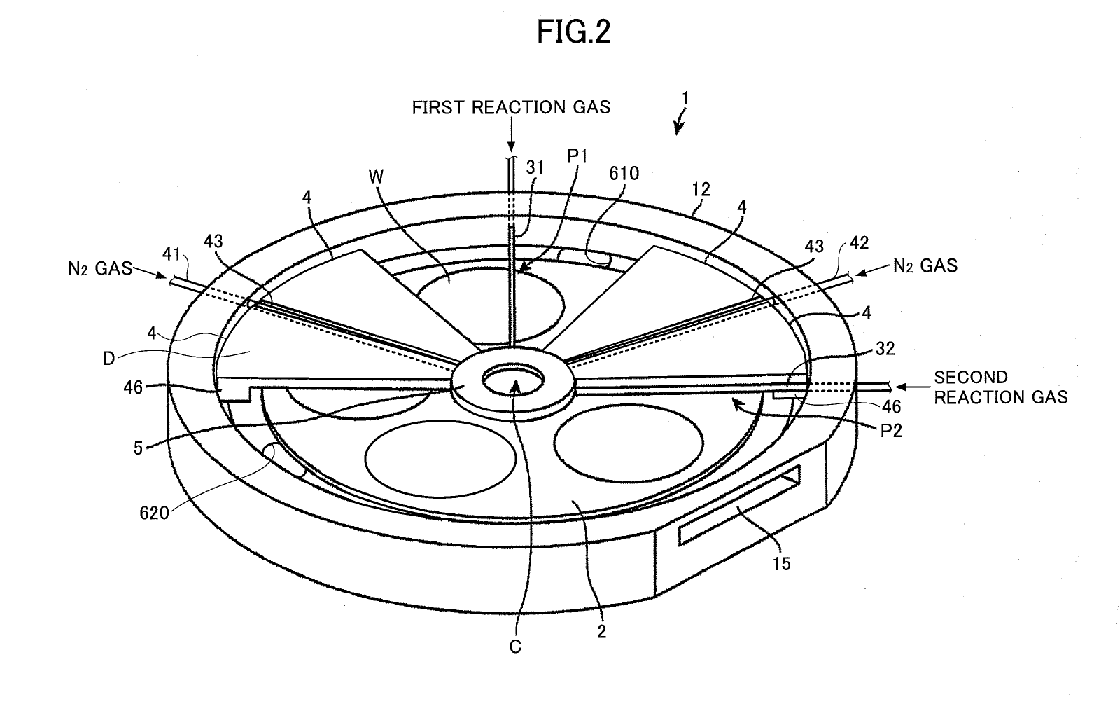

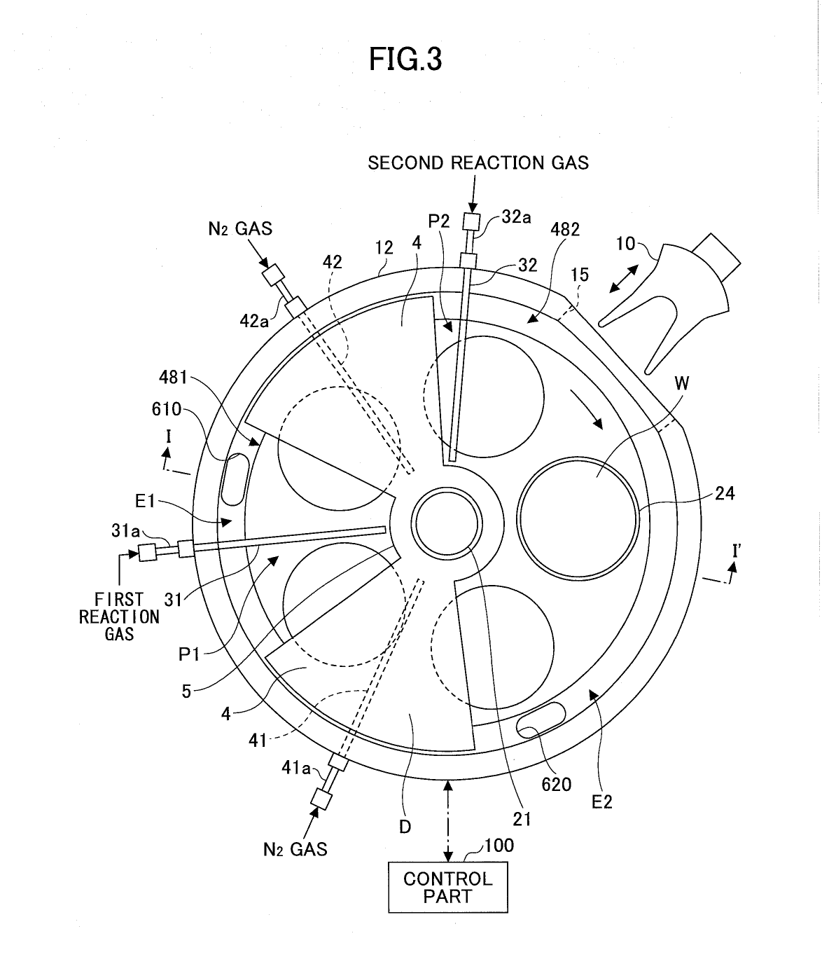

FIG. 1 is a configuration diagram illustrating an example of a substrate ejection detection device and a substrate processing apparatus using the same according to an embodiment of the present invention. FIG. 2 is a perspective view of an inner structure of the substrate processing apparatus to which the substrate ejection detection device of the embodiment of the present invention is applied, and FIG. 3 is a top view of an inner structure of the substrate processing apparatus to which the substrate ejection detection device of the embodiment of the present invention is applied.

Although a variety of apparatuses is available for the substrate processing apparatus as long as the apparatus processes a substrate while rotating a turntable, a description is given by citing an example in which the substrate processing apparatus is configured to be a film deposition apparatus.

With reference to FIGS. 1 through 3, the substrate processing apparatus includes a vacuum chamber 1 whose planar shape is approximately round in shape, and a turntable 2 provided in the vacuum chamber 1 having a center of rotation that coincides with the center of the vacuum chamber 1. As illustrated in FIG. 1, the chamber 1 is a container to hold a substrate to be processed therein and to perform a film deposition process on the substrate. As illustrated in FIG. 1, the chamber 1 includes a ceiling plate 11 and a chamber body 12. The chamber body 12 has a cylindrical shape including a circular bottom. The ceiling plate 11 is configured to be detachable from the chamber body 12. The ceiling plate 11 is hermetically arranged on an upper surface of the chamber body 12 through a sealing member, for example, an O-ring 13 in a way attachable to/detachable from the upper surface of the chamber body 12.

There is a window 16 formed in a part of the ceiling plate 11. For example, a quartz glass is provided to cover the window 16, and the chamber 1 is configured to allow the inside thereof to be visually observed from the outside.

Moreover, the chamber 1 may include an evacuation opening 610 connected to a vacuum pump 640, and may be configured as a vacuum chamber capable of being evacuated.

The turntable 2 is a substrate placement holder to receive a substrate. The turntable 2 has concave portions 24 formed in a surface thereof and having a circular and depressed shape, and supports a substrate on the concave portion 24. FIG. 1 illustrates a state of a semiconductor wafer W being placed on the concave portion 24 as the substrate. Although the substrate is not necessarily limited to the semiconductor wafer W, an example is given hereinafter in which the semiconductor wafer (which is hereinafter called “a wafer”) W is used as the substrate.

The turntable 2 is made of, for example, quartz, and is fixed to a core portion 21 having a cylindrical shape at the central portion. The core portion 21 is fixed to an upper end of a rotational shaft 22 that extends in a vertical direction. As illustrated in FIG. 1, the rotational shaft 22 penetrates through a bottom part 14 of the chamber 1, and the lower end of the rotational shaft 22 is attached to a motor 23 that rotates the shaft 22 around the vertical axis. The rotational shaft 22 and the motor 23 are housed in a cylindrical case body 20 whose upper surface is open. This case body 20 is hermetically attached to a lower surface of the bottom part 14 of the chamber 1 through a flange part 20a provided on an upper surface of the case body 20, by which the internal atmosphere of the case body 20 is separated from the external atmosphere.

In addition, there is an encoder 25 provided at the motor 23 to be able to detect a rotation angle of the rotational shaft 22. The substrate ejection detection device of the present embodiment uses the encoder 25 as an ejection location specifying unit to specify the location of the wafer W out of the concave portion 24 of the turntable 2.

There is a detector 110 provided above the window 16 of the ceiling plate 11. The detector 110 is a unit to detect whether the wafer W exists or not on the concave portion 24 of the turntable 2. A variety of detectors are available for the detector 110 as long as the detectors can detect whether the wafer W exists or not on the concave portion 24. For example, the detector 110 may be a radiation thermometer, and in this case, whether the wafer W exists or not is detected based on a temperature difference between a status of the wafer W present on the concave portion 24 and a status of the wafer W absent on the concave portion 24. Moreover, when detecting whether the wafer W exists or not on the concave portion 24 based on a height of the surface of the concave portion 24, a height detector such as a range finder is used as the detector 110. Thus, the detector 110 can be arbitrarily changed depending on a detection method. A more detailed description is given later in this regard.

A determination part 120 is a unit to determine whether the wafer W exists or not on the concave portion 24 based on the information detected by the detector 110, and is provided as necessary. A proper determination unit may be selected as the determination part 120 depending on a kind of the detector 110. For example, the determination part 120 may be configured as an arithmetic processing unit such as a microcomputer that includes a CPU (Central Processing Unit) and a memory and operates by running a program or an ASIC (Application Specific Integrated Circuit) that is an integrated circuit designed and manufactured for a specific intended use.

Furthermore, the determination part 120 receives a signal from the encoder 25, and determines which wafer W is out of the concave portion 24 when the ejection of the wafer W is detected. The determination part 120 outputs an ejection detection signal to a control part 100 upon determining that the wafer W is out of the concave portion 24.

Here, the detector 110 and the determination part 120 constitutes of an ejection determination unit that determines whether the wafer W is out of the concave portion 24. In addition, the detector 110, the determination part 120 and the encoder 25 constitute of the substrate ejection detection device of the present embodiment.

The control part 100 is a control unit to control the whole of the film deposition apparatus, and may be configured as an arithmetic processing unit. The control part 100 performs control of stopping rotation of the turntable 2 upon receiving the ejection detection signal from the determination part 120 or the detector 110. This makes it possible to promptly stop rotating the turntable 2 when the wafer W is out of the concave portion 24, and to minimize damage to the inside of the chamber 1 and another wafer W, caused by the ejected wafer W.

Moreover, a memory inside the control part 100 stores a program to cause the film deposition apparatus to implement a predetermined method of depositing a film including the stop of rotating the turntable 2 based on the ejection detection of the wafer W from the ejection detection device under the control of the control part 100. This program is constituted of instructions of step groups to cause the film deposition apparatus to implement the predetermined method of depositing a film, stored in a storage medium 102 such as a hard disk, a compact disc, a magnetic optical disk, a memory card and a flexible disk, read by a predetermined reading device into a storage unit 101, and installed into the control part 100.

Next, a description is given below of a configuration of the film deposition apparatus in more detail with reference to FIGS. 2 through 5.

As illustrated in FIGS. 2 and 3, a plurality of circular shaped wafer receiving portions 24 is provided to allow a plurality of (five in the example of FIG. 3) semiconductor wafers to be disposed along a rotational direction (i.e., a circumferential direction) W. In FIG. 3, the wafer W is shown in a single concave portion 24 for convenience. This concave portion 24 has an inner diameter that is slightly greater, for example, 4 mm, than a diameter of the wafer W, and the depth approximately equal to or greater than the thickness of the wafer. Accordingly, when the wafer W is fitted in the concave portion 24, the surface of the wafer W and the surface of the turntable 2 (which means an area where the wafer is not placed) have approximately the same height, or the surface of the wafer W is lower than the surface of the turntable 2. Even when the concave portion 24 is configured to be deeper than the thickness of the wafer W, the depth is preferably configured to be equal to or less than about twice or three times as deep as the thickness of the wafer W because too deep of a concave portion could affect the film deposition. In the bottom surface of the concave portion 24, through-holes to allow lift pins, for example, three of the lift pins for lifting the wafer W by supporting the back surface of the wafer W, to penetrate therethrough are formed (both of which are not shown in the drawings).

FIGS. 2 and 3 are drawings for explaining a structure in the chamber 1, and depiction of the ceiling plate 11 is omitted for convenience of explanation. As illustrated in FIGS. 2 and 3, above the turntable 2, a reaction gas nozzle 31, a reaction gas nozzle 32, and separation gas nozzles 41 and 42 are arranged at intervals in a circumferential direction (in a rotational direction of the turntable 2 (indicated by an arrow A in FIG. 3)) of the vacuum chamber 1. In an example illustrated in FIGS. 2 and 3, a separation gas nozzle 41, the reaction gas nozzle 31, the separation gas nozzle 42, and the reaction gas nozzle 32 are arranged in a clockwise fashion (in the rotational direction of the turntable 2) from a transfer opening 15 described later in this order. These nozzles 31, 32, 41 and 42 are introduced into the vacuum chamber 1 from an external wall by fixing gas introduction ports, which are base end portions of the respective nozzles 31, 32, 41 and 42, to the external wall of the chamber body 12 (see FIG. 3), and are installed so as to extend along a radial direction of the chamber body 12 and to extend parallel to the turntable 2.

The reaction gas nozzle 31 is connected to a first reaction gas supply source (which is not shown in the drawings), through a pipe and a flow rate controller (both of which are not shown in the drawings). The reaction gas nozzle 32 is connected to a second reaction gas supply source (which is not shown in the drawings), through a pipe and a flow rate controller (both of which are not shown in the drawings). The separation gas nozzles 41 and 42 are both connected to a separation gas supply source (which is not shown in the drawings) of, for example, a nitrogen (N₂) gas used as the separation gas, through a pipe and a flow rate controller (both of which are not shown in the drawings).

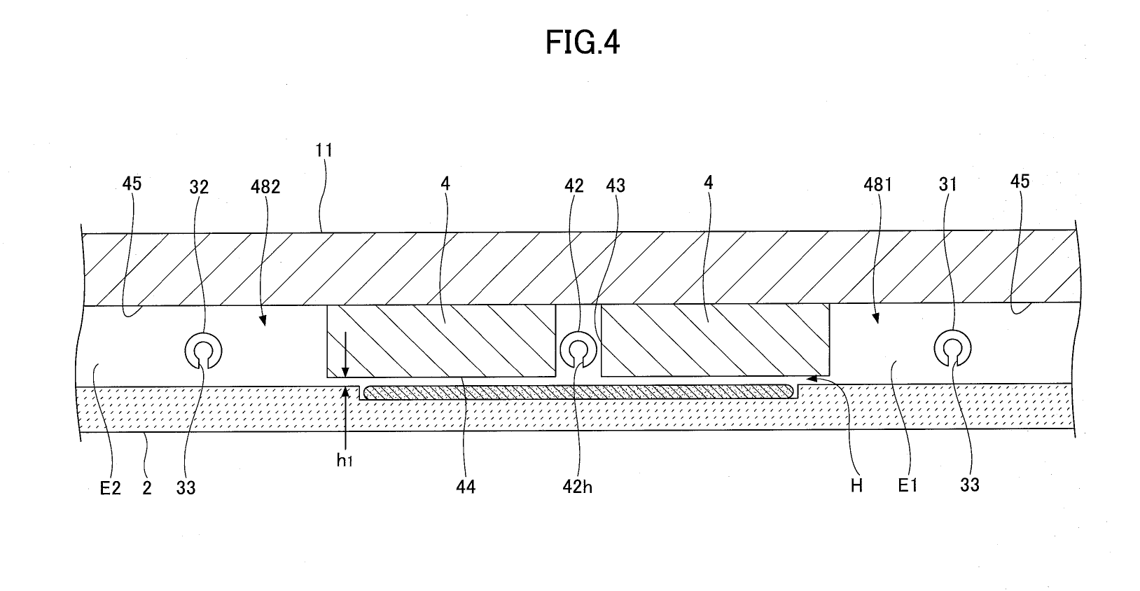

The reaction gas nozzles 31 and 32 include a plurality of gas discharge holes 33 that are open downward facing the turntable 2 (see FIG. 4) and are arranged along lengthwise directions of the reaction gas nozzles 31 and 32 at intervals of, for example, 10 mm. An area under the reaction gas nozzle 31 is a first process area P1 to supply the first reaction gas and to adsorb the first reaction gas on the wafer W. An area under the reaction gas nozzle 32 is a second process area P2 to supply the second reaction gas that reacts with the first reaction gas adsorbed on the wafer W in the first process area P1 and to deposit a reactive product generated from the first reaction gas and the second reaction gas.

With reference to FIGS. 2 and 3, two convex portions 4 are provided in the vacuum chamber 1. The convex portion 4 is attached to the back surface of the ceiling plate 11 so as to protrude toward the turntable 2 in order to form separation areas D with the separation gas nozzles 41 and 42, as described later. Furthermore, the convex portions 4 have an approximately sectorial planar shape whose apex is cut in an arc-like form. In the present embodiment, the inner arc is coupled to a protrusion portion 5 (which is described later), and the outer arc is arranged so as to be along an inner periphery of the chamber body 12 of the vacuum chamber 1.

FIG. 4 illustrates a cross-section of the chamber 1 along the concentric circle of the turntable 2, from the reaction gas nozzle 31 to the reaction gas nozzle 32 of the substrate processing apparatus according to the first embodiment. As illustrated in FIG. 4, because the convex portion 4 is attached to the back surface of the ceiling plate 11, there are flat and low ceiling surfaces 44 (i.e., first ceiling surfaces) that are bottom surfaces of the convex portions 4, and ceiling surfaces 45 (i.e., second ceiling surfaces) that are located on both sides of the ceiling surfaces 44 in the circumferential direction and higher than the ceiling surfaces 44. The convex portions 4 have an approximately sectorial planar shape whose apex is cut in an arc-like form. In addition, as shown in FIG. 4, a groove 43 is formed in the convex portion 4 so as to extend along the radial direction of the turntable 2 at the center in the circumferential direction. The groove portion 43 houses the separation gas nozzle 42. The groove portion 43 is also formed in the other convex portion 4 in a similar way, and houses the separation gas nozzle 41 therein. Furthermore, the reaction gas nozzles 31 and 32 are provided in a space under the high ceiling surfaces 45, respectively. These reaction gas nozzles 31 and 32 are provided in the vicinity of the wafer w apart from the ceiling surfaces 45. Here, as illustrated in FIG. 4, the reaction gas nozzle 31 is provided in a space 481 on the right and under the high ceiling surface 45, and the reaction gas nozzle 32 is provided in a space 482 on the left and under the high ceiling surface 45.

In addition, the separation gas nozzles 41 and 42 include a plurality of gas discharge holes 42h that are open downward facing the turntable 2 (see FIG. 4) and are arranged along lengthwise directions of the separation gas nozzles 41 and 42 at intervals of, for example, 10 mm.

The ceiling surface 44 forms a separation space H that is a narrow space relative to the turntable 2. When an N₂ gas is supplied from the gas discharge holes 42h of the separation gas nozzle 42, the N₂ gas flows to the space 481 and the space 482 through the separation space H. At this time, because a volume of the separation space is smaller than that of the spaces 481 and 482, a pressure of the separation space H can be higher than that of the spaces 481 and 482 by the N₂ gas. In other words, the separation space H having a high pressure is formed between the spaces 481 and 482. Furthermore, the N₂ gas flowing from the separation space H to the spaces 481 and 482 works as a counter flow against the first reaction gas flowing from the first process area P1 and the second gas flowing from the second process area P2. Accordingly, the first reaction gas from the first process area P1 and the second reaction gas from the second process area P2 are separated by the separation space H. Hence, a mixture and a reaction of the first reaction gas and the second reaction gas in the vacuum chamber 1 are reduced.

Here, a height h1 of the ceiling surface 44 relative to the upper surface of the turntable 2 is preferably set at an appropriate height to make the pressure of the separation space H higher than the pressure of the spaces 481 and 482, considering the pressure in the vacuum chamber 1, a rotational speed of the turntable 2, and a supply amount of the separation gas (i.e., N₂ gas) to be supplied.

With reference to FIGS. 1 through 3 again, a protrusion portion 5 is provided on the lower surface of the ceiling plate 11 so as to surround an outer circumference of the core portion 21 that fixes the turntable 2. In the present embodiment, this protrusion portion 5 continuously extends to a region on the rotational center side of the convex portion 4, and the lower surface of the protrusion portion 5 is formed to be the same height as the ceiling surface 44.

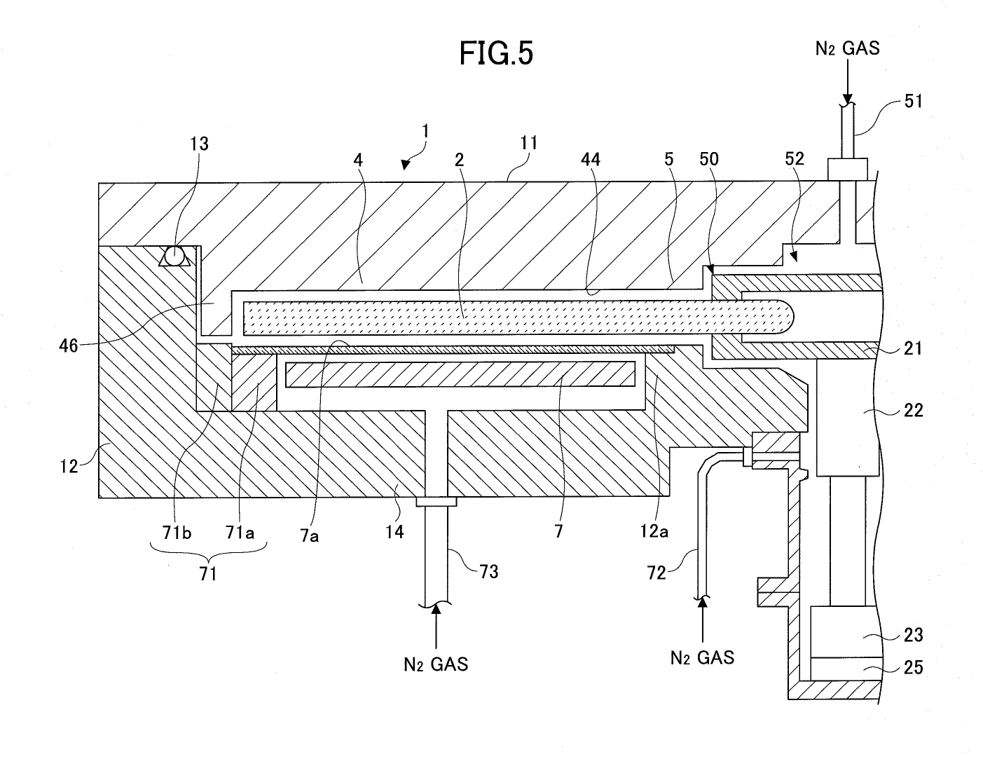

FIG. 1, which was previously referred to, is a cross-sectional view along an I-I′ line in FIG. 3, and illustrates an area where the ceiling surface 45 is provided. On the other hand, FIG. 5 is a partial cross-sectional view illustrating an area where the ceiling surface 44 is provided. As shown in FIG. 5, a bent portion 46 that is bent into an L-letter shape is formed in a periphery of the approximately sectorial convex portion 4 (i.e., a region on the outer edge of the vacuum chamber 1) so as to face the outer edge surface of the turntable 2. The bent portion 46 prevents the reaction gases from flowing into the separation areas D from both sides thereof, and prevents both of the reaction gases from being mixed with each other. Because the sectorial convex portion 4 is provided on the ceiling plate 11, and the ceiling plate 11 is detachable from the chamber body 12, there is a slight gap between the outer periphery of the bent portion 46 and the inner periphery of the chamber body 12. A gap between the inner periphery of the bent portion 46 and the outer edge surface of the turntable 2, and the gap between the outer periphery of the bent portion 46 and the inner periphery of the chamber body are, for example, set at a size similar to a height of the ceiling surface 44 relative to the upper surface of the turntable 2.

As illustrated in FIG. 4, while the inner peripheral wall of the chamber body 12 is formed into a vertical surface close to the outer periphery of the bent portion 46 in the separation areas D, for example, as illustrated in FIG. 1, locations other than the separation areas D are recessed outward from locations facing the outer edge of the turntable 2 throughout the bottom part 14. Hereinafter, for convenience of explanation, depressed portions having a roughly rectangular cross-sectional shape along the radius direction are expressed as evacuation areas. More specifically, as illustrated in FIG. 3, an evacuation area communicated with the first process area P1 is expressed as an evacuation area E1, and an evacuation area communicated with the second process area P2 is expressed as an evacuation area E2. As illustrated in FIGS. 1 through 3, there are a first evacuation opening 610 and a second evacuation opening 620 in the bottom portions of the first evacuation area E1 and the second evacuation area E2, respectively. As shown in FIG. 1, the first evacuation opening 610 and the second evacuation opening 620 are connected to, for example, vacuum pumps 640 of a evacuation unit through evacuation pipes 630, respectively. FIG. 1 also shows a pressure controller 650.

As illustrated in FIGS. 1 and 5, a heater unit 7 that is a heating means is provided in a space between the turntable 2 and the bottom part 14 of the vacuum chamber 1, and the wafer W on the turntable 2 is heated up to a temperature determined by a process recipe (e.g., 450 degrees C.) through the turntable 2. A ring-shaped cover member 71 is provided on the lower side of the periphery of the turntable 2 to prevent a gas from intruding into a space under the turntable 2 by separating an atmosphere in which the heater unit 7 is disposed from an atmosphere from a space above the turntable 2 to the evacuation areas E1 and E2 (see FIG. 5). This cover member 71 includes an inner member 71a provided so as to face the outer edge portion of the turntable 2 and a further outer portion from the lower side, and an outer member 71b provided between the inner member 71a and the inner wall surface of the vacuum chamber 1. The outer member 71b is provided under the bent portion 46 formed in the outer edge portion of the convex portion 4 and close to the bent portion 46, and the inner member 71a is provided to surround the heater unit 7 throughout the whole circumference under the outer edge portion of the turntable 2 (and the slightly further outer portion).

As shown in FIG. 5, the bottom part 14 in a region closer to the rotational center than the space where the heater unit 7 is arranged forms a protrusion part 12a so as to get closer to the core portion 21 in the center portion of the lower surface of the turntable 2. A gap between the protrusion part 12a and the core portion 21 forms a narrow space. Moreover, a gap between an inner periphery of a through-hole of the rotational shaft 22 that penetrates through the bottom part 14 and the rotational shaft 22 is narrow, and the narrow space is in communication with the case body 20. The case body 20 includes a purge gas supply pipe 72 to supply the N₂ gas as a purge gas to the narrow space for purging the narrow space. Furthermore, a plurality of purge gas supply pipes 73 is provided at predetermined angular intervals in the circumferential direction under the heater unit 7 to purge the arrangement space of the heater unit 7 (only one purge gas supply pipe 72 is illustrated in FIG. 5). In addition, a lid member 7a that covers from the inner peripheral wall of the outer member 71b (i.e., the upper surface of the inner member 71a) to the upper end of the protrusion part 12a throughout the circumferential direction is provided between the heater unit 7 and the turntable 2 to prevent the gas from entering the area including the heater unit 7. The lid member 7a can be made of, for example, quartz.

Moreover, as shown in FIG. 5, a separation gas supply pipe 51 is connected to the central part of the ceiling plate 11 of the vacuum chamber 1, and is configured to supply an N₂ gas of the separation gas to a space 52 between the ceiling plate 11 and the core portion 21. The separation gas supplied to the space 52 is discharged toward the outer edge through a narrow space 50 between the protrusion portion 5 and the turntable 2, and along the surface of the turntable 2 on the wafer receiving area side. The space 50 can be maintained at a higher pressure than that of the spaces 481 and 482 by the separation gas. Accordingly, the space 50 serves to prevent the first reaction gas supplied to the first process area P1 and the second reaction gas supplied to the second process area P2 from being mixed through the center area C. In other words, the space 50 (or the center area C) can function as well as the separation space H (or the separation area D).

Furthermore, as shown in FIGS. 2 and 3, a transfer opening 15 is formed in the side wall of the vacuum chamber 1 to transfer the wafer W, which is the substrate, between an external transfer arm 10 and the turntable 2. The transfer opening 15 is configured to be hermetically openable and closeable by a gate valve not shown in FIGS. 2 and 3. Moreover, the wafer W is transferred between the concave portions 24, which are the wafer receiving areas in the turntable 2, and the transfer arm 10 at a position where one of the concave portions 24 faces the transfer opening 15. Accordingly, lift pins for transfer to lift up the wafer W from the back side by penetrating through the concave portion 24 and the lifting mechanism (none of which are shown in the drawing) are provided at the position corresponding to the transfer position under the turntable 2.

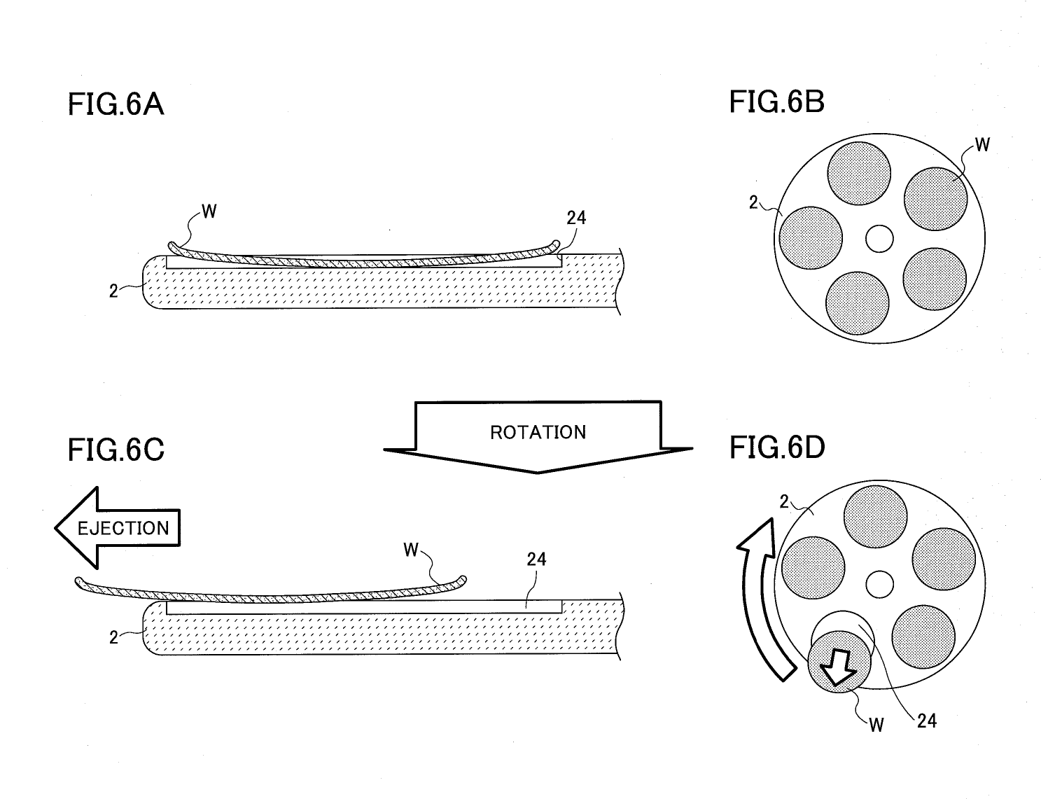

Next, a description is given below of the substrate ejection detection device of the present embodiment in more detail with reference to FIGS. 6A through 13B.

FIGS. 6A through 6D are drawings for explaining ejection of a wafer detected by the substrate ejection detection device of the present embodiment. FIG. 6A is a cross-sectional view illustrating a state of a wafer W being placed on the concave portion 24 formed in the surface of the turntable 2, and FIG. 6B is a top view illustrating a state of the wafer W being placed on the concave portion 24 formed in the surface of the turntable 2.

As illustrated in FIG. 6B, at a glance, each of the five wafers W is placed on the concave portion 24 of the turntable 2. However, as illustrated in FIG. 6A, both ends of one of the wafers W warp upward higher than the surface of the turntable 2, and do not fit in the depth of the concave portion 24 yet.

FIG. 6C is a cross-sectional view illustrating a state having rotated the turntable 2 from the state illustrated in FIGS. 6A and 6B, and FIG. 6D is a top view illustrating a state having rotated the turntable 2 from the state illustrated in FIGS. 6A and 6B.

As illustrated in FIG. 6C, when rotating the turntable 2 from the state of FIG. 6A, a centrifugal force acts on the wafer W, but because the ends of the wafer W do not contact a side surface of the concave portion 24 and are located higher than the surface of the turntable 2, there is no structure to prevent the centrifugal force from causing the wafer W to be out of the concave portion 24.

As illustrated in FIG. 6D, the wafer W that the centrifugal force has acted on is out of the concave portion 24 and flies out of the turntable 2.

In this manner, when the wafer W in the concave portion 24 warps greater than the depth of the concave portion 24 or there is some abnormality, the wafer W is out of and flies out of the concave portion 24 when rotating the turntable 2. When the turntable 2 continues to rotate in this state, since the wafer W collides with the inner wall of inside the chamber 1 and further the centrifugal force and torque act on the wafer W, the wafer W moves by being dragged in the chamber 1, and is liable to cause damage to components and the other wafers in the chamber 1.

The substrate ejection detection device is configured to detect such a substrate ejection status and to be able to control the rotation of the turntable 2 such as stopping the turntable 2. Next, a description is given below of more specific various embodiments of the substrate ejection detection device according to embodiments of the present invention as specific embodiments. All of the description described above can be applied to the following embodiments. In addition, the same numerals are attached to components similar to the components described above, and the description is omitted.

### First Embodiment

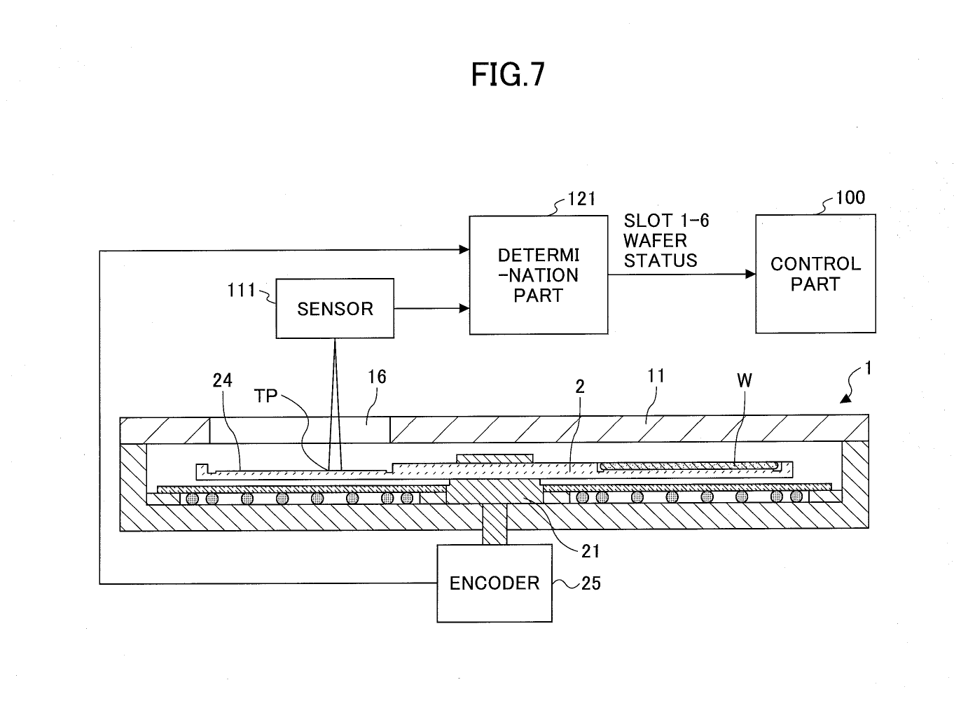

FIG. 7 is a drawing illustrating a configuration of a substrate ejection detection device according to a first embodiment of the present invention. The substrate ejection detection device of the first embodiment includes a radiation thermometer 111, a determination part 121 and an encoder 25. Moreover, a substrate processing apparatus according to a first embodiment of the present invention further includes a chamber 1, a turntable 2 and a control part 100. The substrate ejection detection device of the first embodiment uses the radiation thermometer 111 as a detector.

The radiation thermometer 111 is a thermometer that measures a temperature of an object by measuring an intensity of infrared ray and visible light emitted from the object. By using the radiation thermometer 111, the measurement can be performed rapidly without physical contact. Hence, by providing the radiation thermometer 111 above the window 16 and outside the chamber 1, a wafer temperature at each temperature measurement point TP of each of the concave portions 24 can be measured through the window 16. When the wafer exists on the concave portion 24, the wafer temperature laterally becomes a wafer temperature, but when the wafer W does not exist on the concave portion 24, the temperature at the surface of the concave portion 24 becomes the wafer temperature. Because the turntable 2 made of quartz has emissivity higher than a wafer W made of semiconductor such as Si, when the wafer W does not exist on the concave portion 24, the temperature can be detected higher than when the wafer W exists on the concave portion 24, and generally has a temperature difference of about 10 degrees C. or more. This level of temperature difference is large enough to recognize as a different state. Accordingly, when the radiation thermometer 111 detects the wafer temperature on the concave portion 24 and sends the detection signal to the determination part 121, and then the determination part 121 detects a predetermined temperature difference, it can be determined that the wafer W does not exist on the concave portion 24 and is out of the concave portion 24. Then, at this time, by specifying a location of the concave portion 24 from the rotation angle of the concave portion 24 in which the temperature difference has been detected by using a detection result from the encoder 25, the concave portion 24 in which the ejection of the wafer W has occurred can be specified.

Because the determination part 121 sends an ejection detection signal to the control part 100 when determining that the wafer W is out of the concave portion 24, the control part 100 can perform the control of stopping the rotation of the turntable 2 upon receiving the ejection detection signal. This enables the rotation of the turntable 2 to be rapidly stopped upon detecting the ejection of the wafer W, which can minimize the damage caused by the ejection of the wafer W from the concave portion 24.

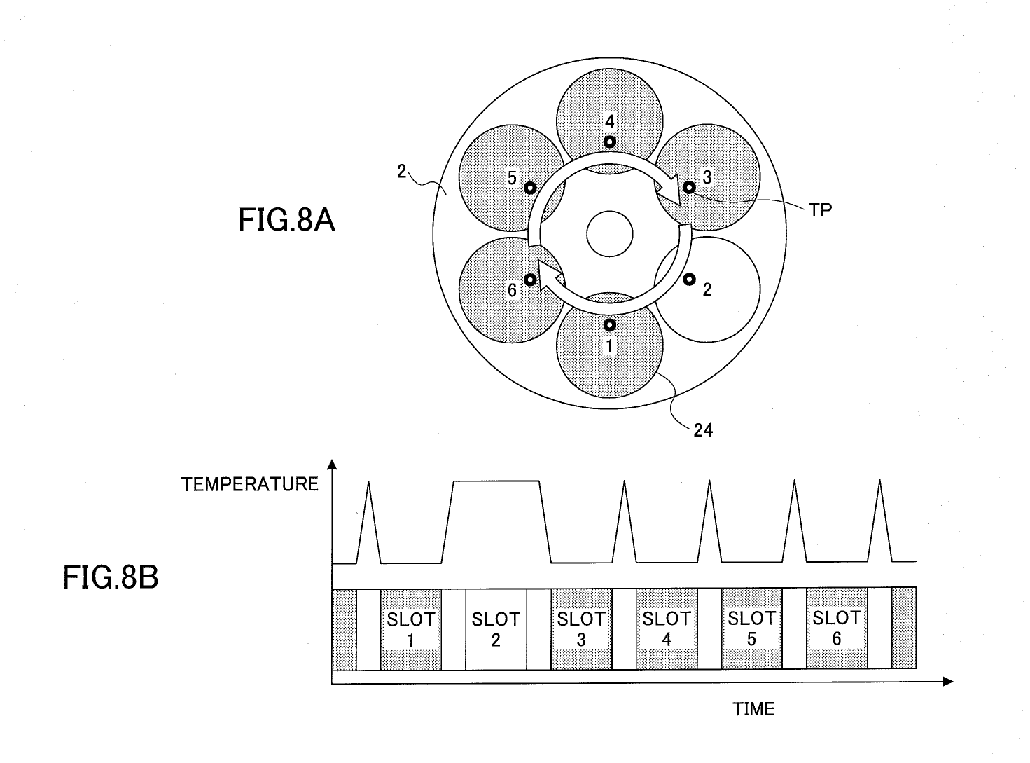

FIGS. 8A and 8B are drawings for explaining detail of the radiation temperature detection and the ejection determination of the substrate ejection detection device according to the first embodiment.

FIG. 8A is a drawing for explaining the radiation temperature detection by the radiation thermometer 111. As illustrated in FIG. 8A, the radiation temperature at a predetermined point of the concave portion 24, more specifically, a temperature measurement point TP on the center line of the wafer W in a radius direction of the turntable 2 and slightly closer to the center of the turntable 2, is detected for each wafer W. Moreover, in FIG. 8A, there is no wafer W on the second concave portion 24 of the six concave portions 24, and there are wafers W on the other five concave portions 24.

FIG. 8B is a diagram illustrating a detection result of a temperature measurement performed by the radiation thermometer 111 is a state of FIG. 8A. As illustrated in FIG. 8B, the temperature is detected at a low flat (i.e., constant) temperature at the concave portion 24 on which the wafer W exists, whereas the temperature increases and pulses are detected at locations where the turntable 2 is exposed between the concave portions 24. Hence, short pulses are detected regularly in an area where the wafers W exist on the concave portions 24, whereas a wide pulse is detected at the second concave portion 24 of which the wafer W is out. Such change of a time period of the pulse makes it possible to detect that the wafer W on the second concave portion 24 is out of the second concave portion 24. Furthermore, by matching the temperature pulse illustrated in FIG. 8 with the pulse of the encoder 25 temporally, which concave portion 24 is the concave portion of which the wafer W is out can be specified.

In this manner, according to the first embodiment of the substrate ejection detection device, by measuring the wafer temperature on the concave portion, the ejection of the wafer W from the concave portion 24 can be readily and certainly detected.

Here, as to the procedure of the substrate ejection detection, the radiation thermometer 111 and the determination part 121 performs a substrate ejection determination process that determines and detects the ejection of the wafer first, and then, an ejection location specifying detection process that specifies the concave portion 24 of which the wafer W is out as necessary. Subsequently, soon after the substrate determination process or after the ejection location specifying process, the determination part 120 sends an ejection detection signal to the control part 100, and the control part 100 carries out a turntable rotation stopping process.

### Second Embodiment

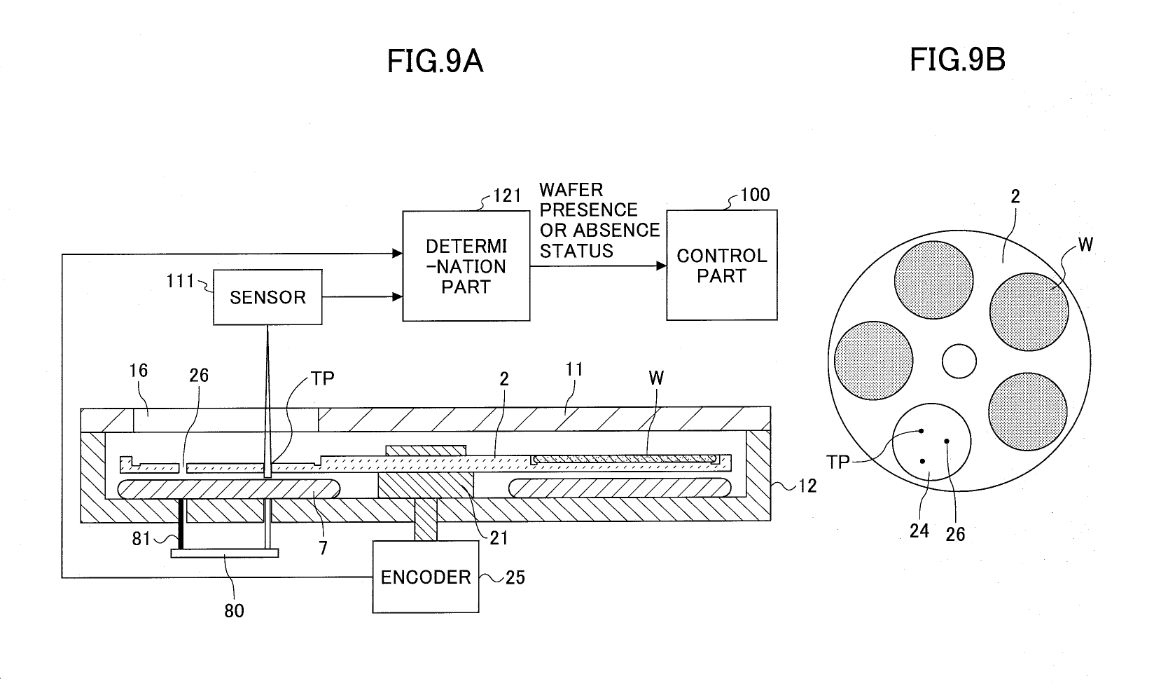

FIGS. 9A and 9B are drawings illustrating an example of a substrate ejection detection device according to a second embodiment of the present invention. FIG. 9A is a cross-sectional view illustrating an example of the substrate ejection detection device according to the second embodiment, and FIG. 9B is a plan view illustrating a detection location of an example of the substrate ejection device according to the second embodiment.

As illustrated in FIG. 9A, the substrate ejection detection device of the second embodiment is similar to the substrate ejection detection device of the first embodiment in terms of including the determination part 121 and the encoder 25, but differs from the substrate ejection detection device of the first embodiment in that the temperature measurement point TP is the through-hole 26 for lifting pin.

The substrate ejection detection device of the second embodiment measures the temperature at the through-hole 26 let through the lifting pin 81 used in transferring the wafer W onto the concave portion 24 instead of the flat portion of the concave portion 24. As illustrated in FIG. 9A, a lifting mechanism 80 is provided under the chamber body 12, and is configured to allow the lifting pins 81 to be able to elevate above the concave portion through the through-hole 26. Because the heater unit 7 is provided under the concave portion 24, by measuring the temperature at the through-hole 26 by the radiation thermometer 111, the direct temperature from the heater unit 7 can be detected. More specifically, the temperature blocked by the wafer W is detected when the wafer W is present on the concave portion 24, but the heat from the heater unit 7 is directly measured when the wafer W is absence on the concave portion 24, by which whether the wafer is present or absence on the concave portion 24 can be determined based on a large temperature difference.

As illustrated in FIG. 9B, although the through-hole 26 is a very small hole, because the radiation thermometer 111 can measure the temperature of the small area from a location apart from the small area, the temperature at the through-hole 26 can be measured without problem. Here, which though-hole 26 is used for the temperature measurement point TP of the plurality of through-holes 26 can be determined depending on intended use.

Although the configuration and the processing detail of the radiation thermometer 111, the determination part 121, the encoder 25 and the control part 100 differ from those in the first embodiment in that the temperature difference made a reference is great and the three levels of temperatures including the temperatures of the wafer W and the surface of the turntable 2 are measured, because the temperature difference between the wafer W and the turntable 2 is about 10 degrees C. and the temperature difference between the through-hole 26 and the wafer W is much greater than the above temperature difference, the detection of the ejection of the wafer W can be readily performed similarly to the first embodiment.

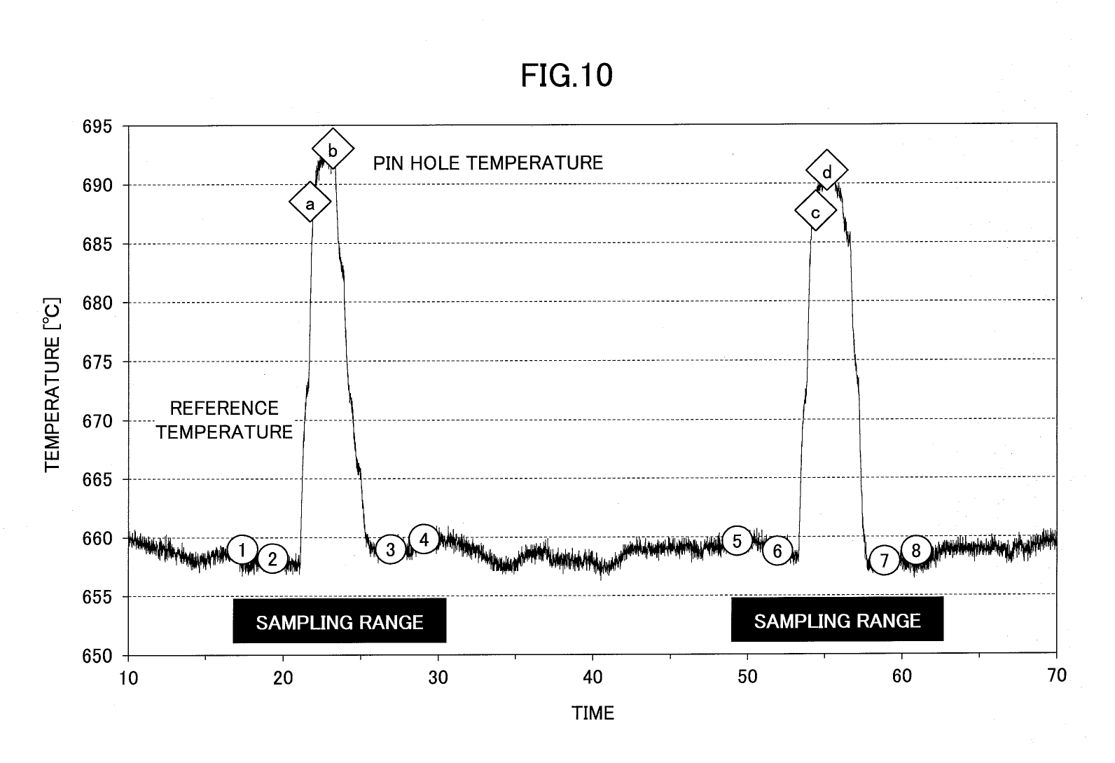

FIG. 10 is a diagram illustrating an example of a substrate ejection determination process performed by the determination part 121 of the substrate ejection detection device according to the second embodiment. In FIG. 10, a transverse axis shows a time, and a longitudinal axis shows a temperature (degrees C.). FIG. 10 illustrates an example of the radiation thermometer 111 installed so that two of the through-holes 26 close to the center of the turntable 2 becomes the temperature measurement points TP of the three through-holes 26 illustrated in FIG. 9B.

As illustrated in FIG. 9B, when an example is given in which four of the concave portions 24 receive the wafers W of the five concave portions 24 and the wafer W is out of one of the five concave portions 24, in this case, as illustrated in FIG. 10, when the radiation thermometer 111 detects temperatures at the through-holes 26 unblocked by the wafer W, peaks of the temperature, which are equal to or higher than 690 degrees C., are detected. In contrast, when temperatures at locations other than the through-holes 26 are detected, the temperatures of about 660 degrees C. are continuously detected. The continuous temperatures are hereinafter called a reference temperature.

In this case, because the temperature difference between the peak values and the reference temperature is 30 degrees C. or more, the determination part 121 can determine that the wafer W is out of the concave portion 24. For example, when the temporal change of the temperature illustrated in FIG. 10 is input into the determination part 121, by sampling data of one point of the reference temperature and data of one point of the peak values and by comparing the sampled data with each other, the ejection of the wafer W from the concave portion 24 can be detected. However, in an actual process, since enhancing reliability of the substrate ejection detection is necessary, the substrate ejection detection may be performed by sampling a plurality of data instead of one point and by using an average value thereof. This enables the reliability of the data to be enhanced and erroneous determination to be prevented.

In FIG. 10, four points of the reference temperature and two points of the thorough-holes 26 (which is hereinafter called a “pin-hole temperature”) are each detected around two peaks. For example, the first reference temperature equals to 657.7 degrees C.; the second reference temperature equals to 655.7 degrees C.; the third reference temperature equals to 658.6 degrees C.; the fourth reference temperature equals to 659.0 degrees C. in the neighborhood of the first peak, and when the through-hole temperature a equals to 687.3 degrees C. and the through-hole temperature b equal to 691.2 are detected, the average of the reference temperatures T_{REF} becomes

T_{REF}=(687.3+691.2)/2=689.3 degrees C.

Also, the average of the pin-hole temperature T_{PIN} becomes

T_{PIN}=(687.3+691.2)/2=689.3 degrees C.

Here, the temperature difference between both of the averages ΔT becomes

ΔT=T_{PIN}−T_{REF}=689.3−658.2=31.1 degrees C.,

because there are enough temperature difference of equal to or more than 30 degrees C., the ejection of the wafer W can be naturally determined.

Thus, by setting the number of sampling of the reference temperature and the pin-hole temperature at a plurality of times, calculating an average value of the plurality of data, and performing the ejection determination by using the average value, erroneous determination in the ejection determination can be prevented and the reliability of the ejection determination performed by the determination part 121 can be enhanced. With respect to the sampling, because the location of the concave portion 24 can be knew by the encoder 25, when the radiation thermometer 111 detects the temperature around the through-hole 26, it is only necessary to set a predetermined time range around the through-hole 26 at a sampling range and to sample the temperature a plurality of times at predetermined intervals within the predetermined time range. Moreover, although the description is given of the number of sampling by giving the example of four times about the reference temperature and twice about the pin-hole temperature in FIG. 10, the number of sampling can be set at a proper number depending on intended use.

In this manner, in the substrate ejection detection device and the method of detecting the ejection of the substrate, the number of sampling for acquiring data to perform the ejection detection may be made multiple times and the substrate ejection determination may be performed by using the average value of the reference temperatures and the pin-hole temperatures. This enables the erroneous determination to be prevented and the reliability of the ejection determination to be enhanced. Furthermore, when the detected data has high reliability and it is sufficient to acquire only one sampling value regarding both of the reference temperature and the pin-hole temperature, only one sampling may be performed for each. Thus, the data processing in the ejection determination can take a variety of forms.

In addition, the ejection position determination process and the turntable stopping process after the ejection determination process can be performed similarly to the substrate ejection detection device and the method of detecting the substrate ejection of the first embodiment.

According to the substrate ejection detection device and the method of detecting the substrate ejection of the second embodiment, by using the through-hole 26, the temperature of the heat directly from the heater 7 can be compared with the temperature of the surface of the wafer W, and the ejection determination of the wafer W can be performed based on the large temperature difference.

### Third Embodiment

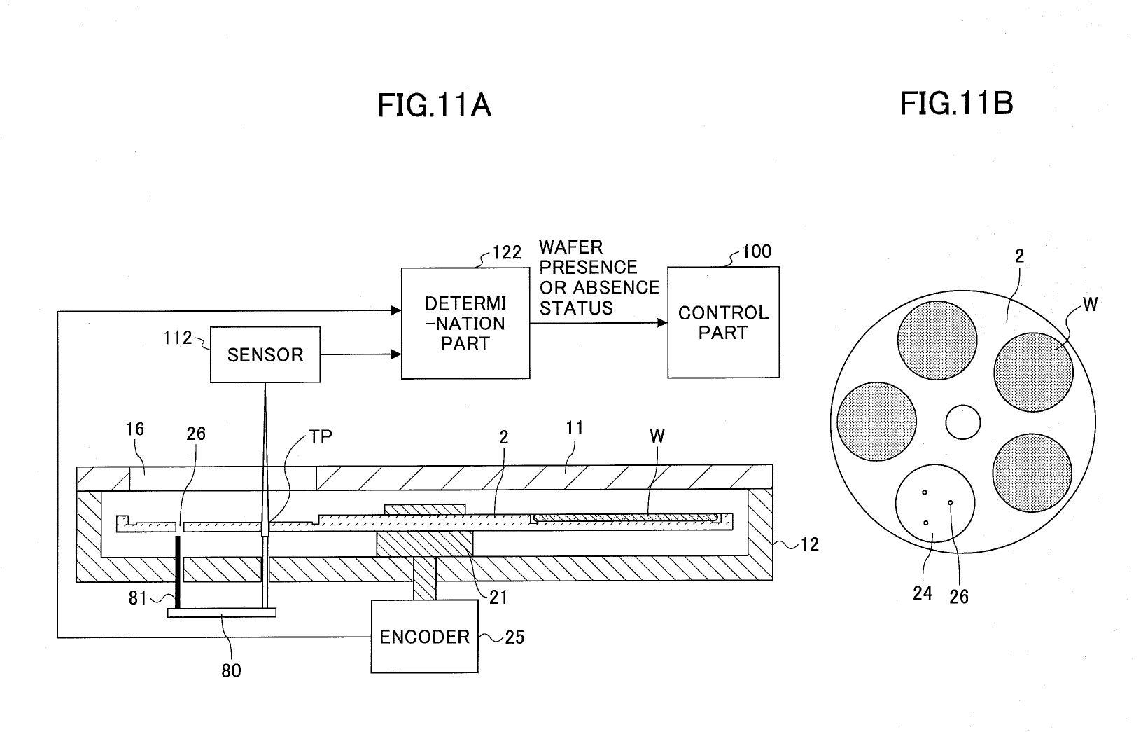

FIGS. 11A and 11B are drawings illustrating an example of a substrate ejection detection device according to a third embodiment of the present invention. FIG. 11A is a cross-sectional view illustrating an example of a configuration of the substrate ejection detection device of the third embodiment, and FIG. 11B is a plan view illustrating a detection location of an example of the substrate ejection detection device of the third embodiment.

As illustrated in FIGS. 11A and 11B, the substrate ejection detection device of the third embodiment uses an optical detector 112 as a detector, and detects the through-hole 26 of the lifting pin 81 as a detection object. For example, by using a reflective optical sensor or a transmission type optical sensor using a light beam such as an infrared ray as the optical detector 112, and by detecting the presence or absence of the through-hole 26, whether the wafer W exists on the concave portion 24 or not is determined.

For example, when the reflective optical sensor is used as the optical detector 112, the reflective optical sensor emits light to the location where the through-hole 26 exists. Reflected light is detected when the wafer W exists, whereas the reflected light is not detected when the wafer W does not exist, based on which whether the wafer W exists or not is determined.

Moreover, when using the transmission type optical sensor as the optical detector 112, a pair of a projector and an optical receiver is installed on a vertical line passing through the through-hole 26 on the upper side and the lower side of the through-hole 26, and it is determined that the wafer W is absent when the optical receiver detects the light from the projector and that the wafer W is present when the optical receiver does not detect the light from the projector.

Furthermore, a determination part 122 determines whether the wafer W exists or not on the concave portion 24 based on the detection of the light from the optical detector 112. The determination part 122 is naturally configured to perform the determination appropriate for the reflective optical sensor or the transmission type optical sensor. Here, since the other components are similar to those in the second embodiment, the same numerals are attached to the similar components and the description is omitted.

According to the substrate ejection detection device and the method of detecting the substrate ejection, the ejection of the wafer W from the concave portion 24 can be readily and certainly detected by using the optical detector 112.

### Fourth Embodiment

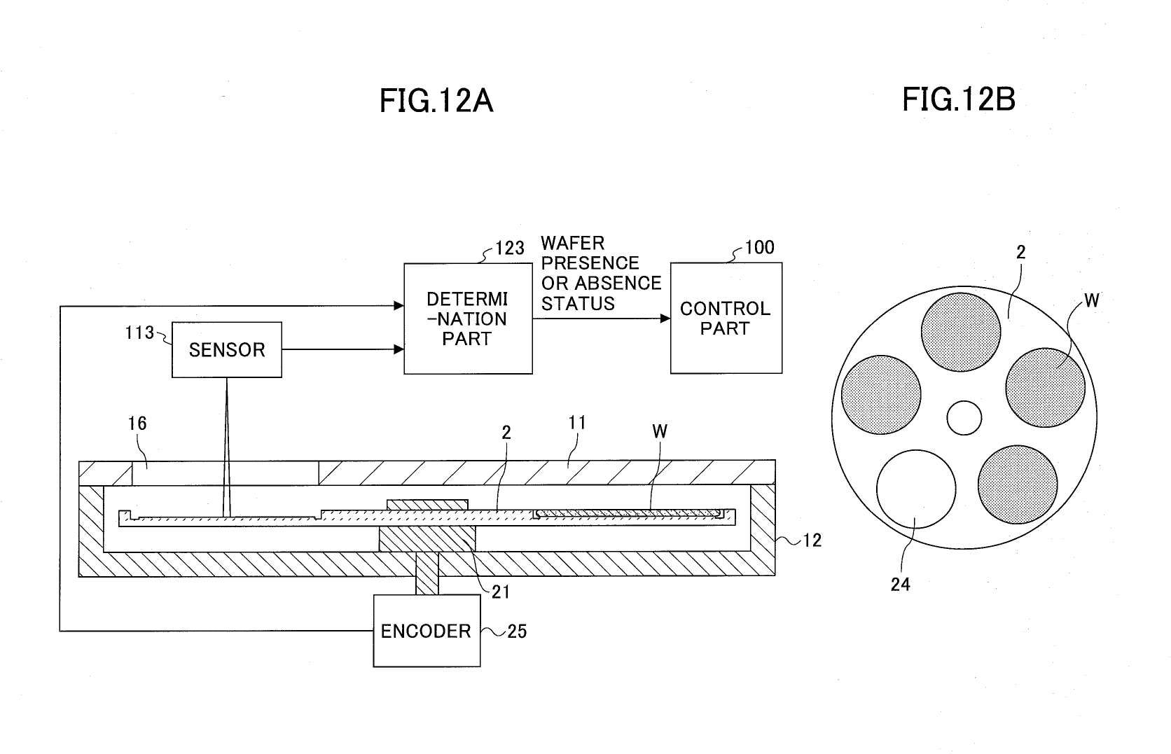

FIGS. 12A and 12B are drawings illustrating an example of a substrate ejection detection device according to a fourth embodiment of the present invention. FIG. 12A is a cross-sectional view illustrating an example of a configuration of the substrate ejection detection device according to the fourth embodiment, and FIG. 12B is a plan view illustrating a detection location in an example of the substrate ejection detection device according to the fourth embodiment.

The substrate ejection detection device of the fourth embodiment uses a height detector 113 that detects a height of the surface of the turntable 24 as a detector thereof. As to the height detector 113, a range finder and the like are taken as an example. As to the range finder, utilizing a range finder using an infrared ray rather than a laser beam is preferable so as not to give damage to a surface of a wafer W. Because the height of the surface in the concave portion 24 becomes high by a thickness of the wafer W when the wafer W exists on the concave portion 24, the height of the surface in the concave portion 24 becomes lower than the location including the wafer W by the thickness of the wafer W when the wafer W does not exist on the concave portion 24. In this manner, according to the substrate ejection detection device and the method of detecting the substrate ejection of the fourth embodiment, the height of the surface of the concave portion 24 is detected, and whether the wafer W exists on the concave portion or not is detected by utilizing the thickness of the wafer W.

Here, the determination part 123 is configured to perform arithmetic processing to determine whether the wafer W exists or not on the concave portion 24 based on the height of the surface of the concave portion 24 detected by the height detector 113.

In addition, since the other components and functions are similar to those in the first embodiment, the same numerals are attached to the similar components and the description is omitted.

### Fifth Embodiment

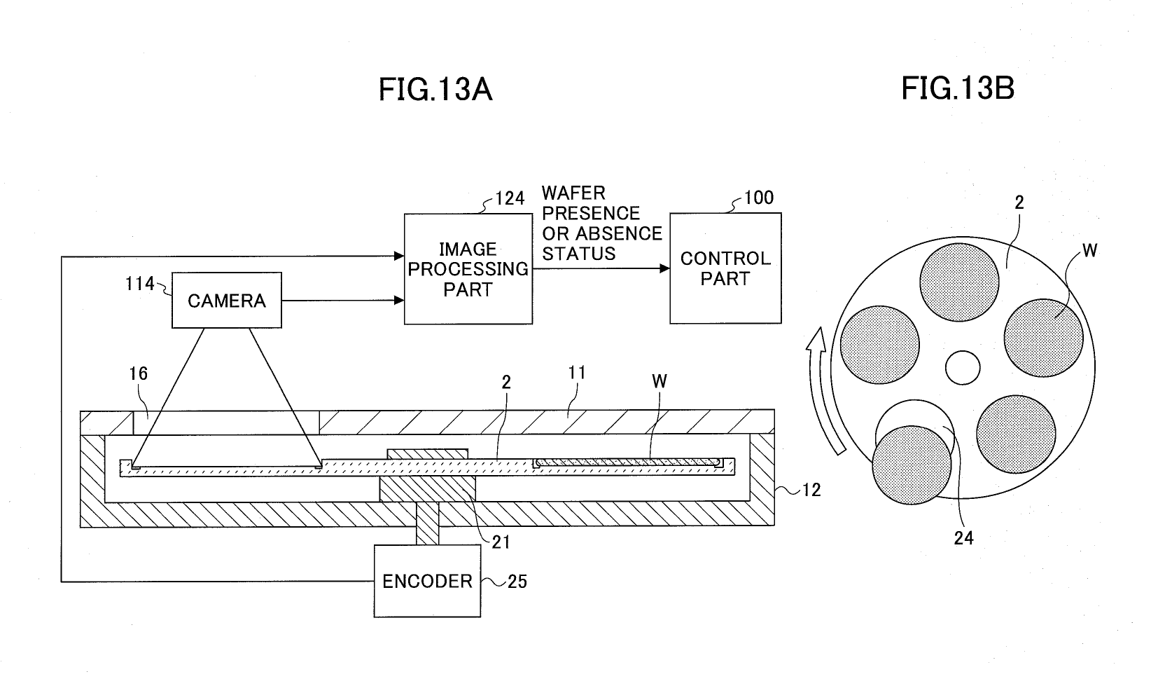

FIGS. 13A and 13B are drawings illustrating an example of a substrate ejection detection device according to a fifth embodiment of the present invention. FIG. 13A is a cross-sectional view illustrating a configuration of an example of the substrate ejection detection device of the fifth embodiment, and FIG. 13B is a top view illustrating a detection location of an example of the substrate ejection detection device of the fifth embodiment.

As illustrated in FIGS. 13A and 13B, the substrate ejection detection device of the fifth embodiment uses an imaging device 114 such as a camera as a detector, and determines the ejection of the wafer W from the concave portion 24 by image processing. More specifically, the substrate ejection detection device obtains an image of the concave portion 24 by the imaging device 114, processes the image by an image processing part 124, and determines the presence or absence of the wafer W on the concave portion, that is to say, whether the wafer W is ejected or not from the concave portion 24.

Since the other components and functions thereof are similar to those of the first embodiment, the same numerals are attached to the similar components and the description is omitted.

According to the substrate ejection detection device and the method of detecting the substrate ejection of the fifth embodiment, the ejection of the wafer W from the concave portion 24 can be directly detected by using the imaging device 114.

As described above, according to embodiments of the present invention, ejection of a substrate from a turntable can be certainly detected.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention.

What is claimed is:

1. A substrate ejection detection device of a substrate processing apparatus configured to process a substrate by continuously rotating a turntable holding the substrate on a concave portion formed in a surface thereof to receive the substrate thereon, the turntable being substantially horizontally provided in a chamber, the substrate ejection detection device comprising:
a substrate ejection determination unit configured to determine whether the substrate is out of the concave portion by determining whether the substrate exists on the concave portion while rotating the turntable.

2. The substrate ejection detection device as claimed in claim 1,
wherein one or more concave portions are formed in the surface of the turntable along a circumferential direction of the turntable in addition to the concave portion, and further comprising:
an ejection location specifying unit configured to specify a location of the concave portion of which the substrate is out when the substrate ejection determination unit detects the ejection of the substrate from the concave portion.

3. The substrate ejection detection device as claimed in claim 2, wherein the ejection location specifying unit is an encoder configured to detect a rotation position of a rotational shaft of the turntable.

4. The substrate ejection detection device as claimed in claim 1, wherein the substrate ejection determination unit includes a thermometer to detect a temperature of the substrate on the concave portion, and determines whether the substrate exists or not on the concave portion based on a temperature difference between presence and absence of the substrate.

5. The substrate ejection detection device as claimed in claim 4, wherein the thermometer is a radiation thermometer provided apart from the turntable.

6. The substrate ejection detection device as claimed in claim 5,
wherein the concave portion includes a through-hole formed therein to allow a lifting pin that transfers the substrate on the concave portion to pass therethrough, and
wherein the radiation thermometer is installed so as to detect a location different from the through-hole, and
wherein the substrate ejection determination unit determines whether the substrate exists or not on the concave portion based on a temperature difference caused by an emissivity difference between the turntable and the substrate.

7. The substrate ejection detection device as claimed in claim 5,
wherein the concave portion includes a through-hole formed therein to allow a lifting pin that transfers the substrate on the concave portion to pass therethrough, and
wherein a heater is provided under the turntable, and
wherein the radiation thermometer is installed so as to detect a temperature of the through-hole, and
wherein the substrate ejection determination unit determines whether the substrate exists or not on the concave portion based on a temperature difference between a heater temperature detected from the through-hole and a substrate temperature.

8. The substrate ejection detection device as claimed in claim 1, wherein the substrate ejection determination unit includes a height detection unit configured to detect a height of a surface in the concave portion, and determines whether the substrate exists or not on the concave portion based on a height difference of the surface in the concave portion.

9. The substrate ejection detection device as claimed in claim 8, wherein the height detection unit is a range finder provided apart from the turntable.

10. The substrate ejection detection device as claimed in claim 1,
wherein the concave portion includes a through-hole formed therein to allow a lifting pin that transfers the substrate on the concave portion to pass therethrough, and
wherein the substrate ejection determination unit includes an optical detector configured to detect whether the through-hole exists or not.

11. The substrate ejection detection device as claimed in claim 10, wherein the optical detector is a transmission type optical sensor.

12. The substrate ejection detection device as claimed in claim 10, wherein the optical detector is a reflective optical sensor.

13. The substrate ejection detection device as claimed in claim 1,
wherein the substrate ejection determination unit includes an imaging unit configured to take an image of the concave portion, and
an image processing unit configured to determine whether the substrate exists or not on the concave portion by processing the image taken by the imaging unit.

14. The substrate ejection detection device as claimed in claim 1,
wherein the chamber includes a window formed in an upper surface therein to allow an inside of the chamber to be visually observed, and
wherein the substrate ejection determination unit is provided outside the chamber, and determines whether the substrate is out of the concave portion through the window.

15. A substrate processing apparatus,
comprising:
a chamber;
a turntable substantially horizontally provided in the chamber and including a concave portion formed in a surface thereof to receive the substrate thereon; and
a substrate ejection determination unit configured to determine whether the substrate is out of the concave portion by determining whether the substrate exists on the concave portion while rotating the turntable.

16. A method of detecting substrate ejection in substrate processing apparatus configured to process a substrate by continuously rotating a turntable holding the substrate on a concave portion formed in a surface thereof to receive the substrate thereon, the method comprising steps of:
determining whether the substrate is out of the concave portion by determining whether the substrate exists or not on the concave portion while rotating the turntable.

17. The method as claimed in claim 16,
wherein one or more concave portions are formed along a circumferential direction of the turntable in the surface of the turntable in addition to the concave portion, and further comprising a step of:
specifying a location of the concave portion of which the substrate is out when detecting the ejection of the substrate from the concave portion.

18. The method as claimed in claim 17, wherein the step of specifying the location of the concave portion of which the substrate is out is performed by using an encoder configured to detect a rotation angle of a rotational shaft of the turntable.

19. The method as claimed in claim 16,
wherein the step of determining whether the substrate is out of the concave portion is performed by detecting a temperature of the substrate on the concave portion and by determining whether the substrate exists or not on the concave portion based on a temperature difference between a presence and absence of the substrate.

20. The method as claimed in claim 19, wherein the temperature of the substrate is detected by using a radiation thermometer provided apart from the turntable.
